(19) United States
(12) Patent Application Publication
(10) Pub. No.: US 2012/0270017 A1
(43) Pub. Date: Oct. 25, 2012

(54) Kitchenware with patterns on its surface and manufacture method thereof

(75) Inventor: Chris Pok Man Chau, New Territories (HK)

(73) Assignee: Millennium Metal & Plastic Co. Ltd., New Territories (HK)

(21) Appl. No.: 13/287,987

(22) Filed: Nov. 2, 2011

(30) Foreign Application Priority Data
Apr. 21, 2011 (CN) 201120119706.1

(51) Int. Cl. B32B 3/00; C23C 14/02

(52) U.S. Cl. 428/195.1; 427/596

(57) ABSTRACT

A kitchenware with surface patterns and a manufacture method thereof; the kitchenware comprises: a hand-held part and food contact part; the hand-held part and/or food contact part covered with a color layer divided into a first region without a laser engraving process and a second region formed by laser engraving; the thickness of the second region is smaller than that of the first region; the first and second regions form preset patterns; a protection layer covers the color layer. The manufacture method comprises: manufacturing the hand-held and food contact parts of the kitchenware with preset color; covering surfaces of the hand-held and/or food contact parts with a color layer; determining an engraving region and engraving depth according to preset patterns, engraving the color layer with laser; and covering the color layer with a protection layer. The kitchenware has aesthetic patterns, a flat surface, improved non-stick performance, and is cleaned easily.

### CROSS-REFERENCE TO RELATED APPLICATION

This application claims priority to China application no. 201120119706.1 filed on Apr. 21, 2011, which is hereby incorporated by reference in its entirety.

### FIELD OF THE INVENTION

The present invention relates to a kitchenware, more specifically, relates to a kitchenware with patterns on its surface and a manufacture method thereof.

### BACKGROUND OF THE INVENTION

In the prior art, as there are no patterns on a hand-held part or a food contact part of the kitchenware such as rice scoop and spoon, the kitchenware may not be so beautiful. Or the patterns may be directly sprayed onto the kitchenware. The formed patterns are so rough or not fine enough, that they may not only severely affect the aesthetics of kitchenware but also cause roughness on the surface of kitchenware, making it easily stained and difficult to clean.

### SUMMARY OF THE INVENTION

One objective of the present invention is to provide a kitchenware with patterns on its surface, which has aesthetic patterns and a flat surface so as to improve its non-stick performance and is easy to clean.

Another objective of the present invention is to provide a manufacture method for manufacturing the kitchenware with patterns on its surface, which is simple and feasible to achieve fine and aesthetic patterns.

According to an embodiment of the present invention, the objectives stated above are achieved by the following technical solution. A kitchenware with patterns on its surface is provided, which comprises a hand-held part and a food contact part; wherein the hand-held part and/or the food contact part are covered with a color layer; the color layer is divided into a first region without a process of laser engraving and a second region formed by laser engraving, the thickness of the second region being smaller than that of the first region; the first region and the second region form the preset patterns; the color layer is covered with a protection layer.

In the kitchenware with patterns on its surface of the present invention, the second region is divided into at least one subregion according to the differences of the thickness of color layer.

In the kitchenware with patterns on its surface of the present invention, the second region is divided into a first subregion and a second subregion, the thickness of the first subregion being smaller than that of the first region and the thickness of the first subregion being larger than that of the second subregion.

In the kitchenware with patterns on its surface of the present invention, the thickness of the first subregion accounts for 70% to 99.9% of that of the first region, while the thickness of the second subregion is zero.

In the kitchenware with patterns on its surface of the present invention, the thickness of the second region accounts for 70% to 99.9% of that of the first region.

In the kitchenware with patterns on its surface of the present invention, the thickness of the second region is zero.

In the kitchenware with patterns on its surface of the present invention, the kitchenware is tableware or a kitchen ware.

The present invention further discloses a manufacture method for manufacturing a kitchenware with patterns on its surface, comprising the following steps:

S1. manufacturing a hand-held part and a food contact part with preset color of a kitchenware;

S2. covering the surfaces of the hand-held part and/or the food contact part of the kitchenware with a color layer;

S3. determining an engraving region and an engraving depth according to the preset patterns, and then engraving the color layer with laser;

S4. covering the color layer with a protection layer.

In the manufacture method of a kitchenware with patterns on its surface of the present invention, in step S1, the hand-held part and the food contact part are manufactured by injection moulding or compression moulding etc.; the hand-held part and the food contact part have real color, or semitransparent color, or transparent color.

In the manufacture method of a kitchenware with patterns on its surface of the present invention, the kitchenware is tableware or a kitchen ware.

When implementing the kitchenware with patterns on its surface and the manufacture method of such kitchenware of the present invention, following advantageous effects will be obtained: the hand-held part and/or the food contact part of the kitchenware of the present invention are covered with a color layer which is divided into several regions with different thicknesses. The color of the color layer with different thicknesses overlays on the color of the hand-held part and/or the food contact part, resulting different color effects and forming patterns on the surface of the kitchenware. The color layer is covered with a protection layer, which is capable of displaying the patterns, protecting the color layer effectively at the same time, preventing the color layer from coming off and realizing a flat surface of the kitchenware. By this method, the flat surface of the kitchenware is not easily stained; therefore such kitchenware is easy to clean and more healthy for usage. In the manufacture method of such kitchenware of the present invention, a color lay is processed by laser engraving and divided into several regions with different thicknesses. Two kinds of colors are enough to be utilized to realize the coordination of two, three or more kinds of colors. The laser engraving technology can make the patterns fine and aesthetic. The manufacture method is simple and feasible.

### BRIEF DESCRIPTIONS OF THE DRAWINGS

The present invention will be further illustrated with reference to the following embodiments and accompanying drawings. In the figures:

FIG. 1 is a structural diagram of the kitchenware according to the first embodiment of the present invention;

FIG. 2 is a structural diagram of the kitchenware according to the second embodiment of the present invention;

FIG. 3 is a structural diagram of the kitchenware according to the third embodiment of the present invention.

### DETAILED DESCRIPTION OF SPECIFIC EMBODIMENTS

To make the technical features, objectives and effects more clear to be understood, the embodiments of the present invention will be described in details with reference to accompanying drawings.

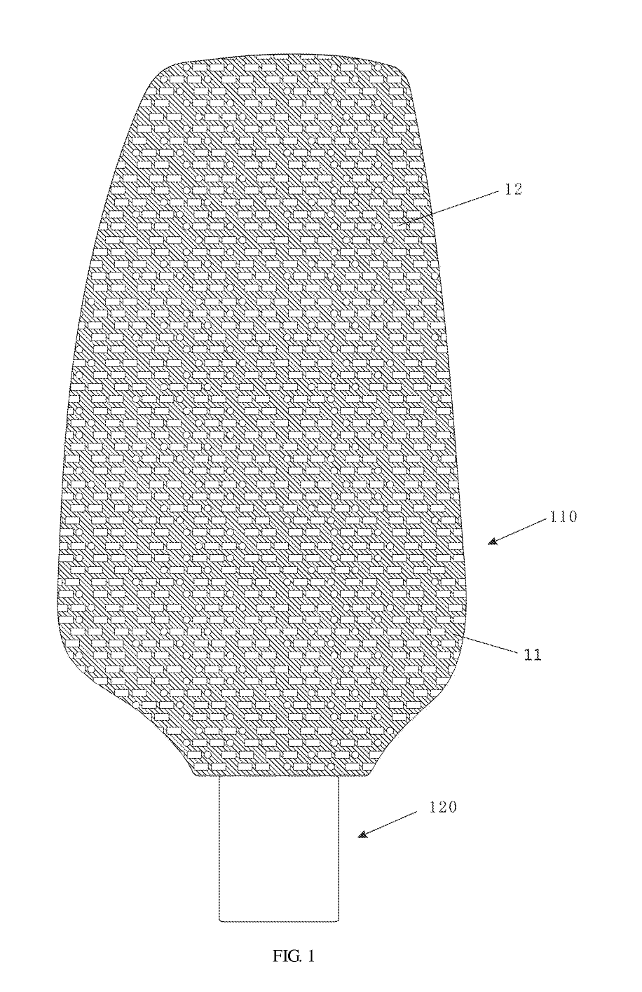

As shown in FIG. 1, a kitchenware with patterns on its surface in the first embodiment of the present invention comprises a hand-held part 120 and a food contact part 110. Preferably, the food contact part 110 is made of plastics or silicone rubber. The hand-held part 120 and the food contact part 110 can be manufactured by means of injection moulding, or compression moulding etc. Then a color layer is covered on the surface of the food contact part by spraying, or silk screen etc., that is, a color layer for covering is set on the surface of food contact part 110. The color layer is divided into a first region 11 without a process of laser engraving and a second region 12 formed by laser engraving. The first region 11 is the region with oblique lines in the food contact part 110 in FIG. 1, and the second region 12 is the blank region in the food contact part 110 in FIG. 1.

The thickness of the second region 12 is smaller than that of the first region 11; preset patterns are formed by the first region 11 and the second region 12. An engraving region and an engraving depth are determined according to the preset patterns. That is, the position and the size of the second region are determined; then the engraving depth is determined according to the thickness of the second region 12. Preferably, the thickness of the second region 12 accounts for 70% to 99.9% of that of that first region 11, which means the laser engraved depth accounts for 0.1% to 30% of the thickness of the color layer itself in the first region 11; thus the color of the first subregion 23 can overlay on and blend with the intrinsic color of the food contact part of the kitchenware much better. The color of the color layer is different from that of the surface of the food contact part 110. The intrinsic color of the color layer is dark grey, while the intrinsic color of the food contact part 110 is green. Therefore, the color of the first region 11 is dark grey while the color of the second region 12 is eventually the color produced by the overlay of green on dark grey color. Since the eventual colors of the first region 11 and the second region 12 are different, patterns are formed on the surface of the food contact part 110.

A transparent protection layer is covered on the color layer by means of spraying, or silk screen etc. The protection layer can display the patterns, protect the color layer effectively and prevent the color layer from coming off. Meanwhile, it can fill the concaves and convexes produced by engraving, so as to realize a flat surface of food contact part 110. Stains do not easily remain on the flat surface of food contact part 110; therefore the food contact part 110 is easy to clean.

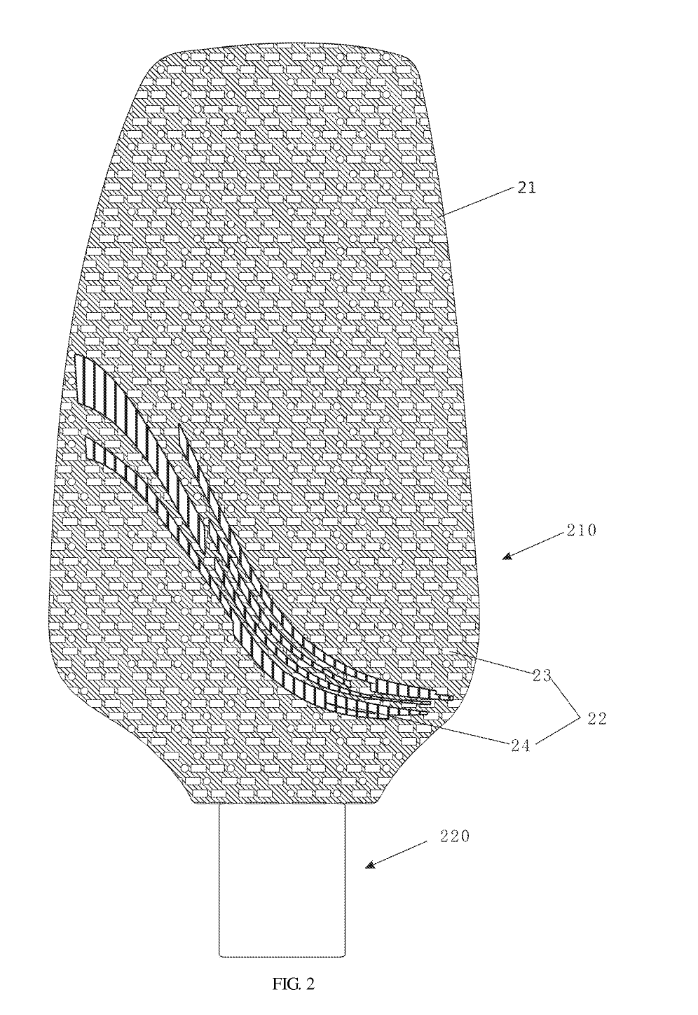

As shown in FIG. 2, the kitchenware with patterns on its surface in the second embodiment of the present invention comprises a hand-held part 220 and a food contact part 210. Preferably, the food contact part 210 is made of plastics or silicon resin. The hand-held part 220 and the food contact part 210 can be manufactured by means of injection moulding, or compression moulding etc. Then a color layer is covered on the surface of the food contact part by means of spraying, or silk screen etc., that is, a color layer is covered on the surface of the food contact part 210. The color layer is divided into a first region 21 without a process of laser engraving and a second region 22 formed by laser engraving. The second region 22 is divided into a first subregion 23 and a second subregion 24 according to the differences of the thickness of the color layer. The first region 21 is the region with oblique lines in the food contact part 210 in FIG. 2, the first subregion 23 is the blank region in the food contact part 210 in FIG. 2, and the second subregion 24 is the region with vertical lines in the food contact part 210 in FIG. 2.

The thickness of first subregion 23 is smaller than that of the first region 21, but is larger than that of the second subregion 24. Preset patterns are formed by the first region 21, the first subregion 23 and the second subregion 24. Preferably, the thickness of first subregion 23 accounts for 70% to 99.9% of that of first region 21, that is, the engraved depth accounts for 0.1% to 30% of the thickness of first region 21; thus the color of first subregion 23 can overlay on and blend with the intrinsic color of food contact part 210 much better. The thickness of second subregion 24 is zero, which means the second subregion 24 has been completely removed by laser engraving so as to reveal the surface of the food contact part 210. The color of the color layer is different from that of the surface of food contact part 210. The intrinsic color of the color layer is dark grey, while that of the food contact part 210 is green. Therefore, the eventual color of first region 21 is dark grey while the color of the first subregion 23 is eventually the color produced by the overlay of green on dark grey color. The eventual color of second subregion 24 is the intrinsic color of the food contact part 210 (i.e. green). Since the eventual colors of first region 21, first subregion 23 and second subregion 24 are different from each other, patterns are formed on the surface of food contact part 210.

A protection layer is covered on the color layer by means of spraying, or silk screen etc. The protection layer can protect the color layer effectively and prevent the color layer from coming off. Meanwhile it can fill the concaves and convexes caused by engraving, so as to realize a flat surface of food contact part 210. Stains do not easily remain on the flat surface of food contact part 210; therefore the food contact part 210 with its non-stick performance improved is easy to clean.

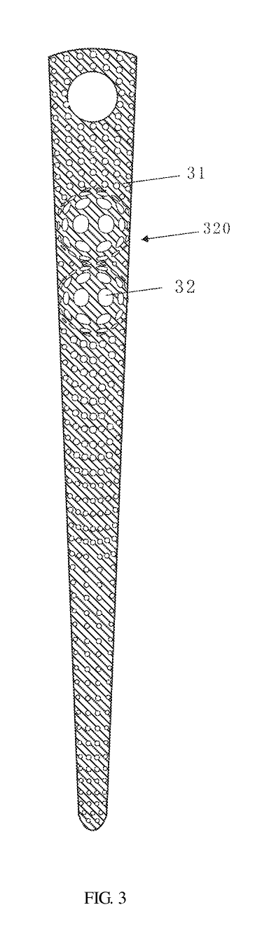

As shown in FIG. 3, the kitchenware with patterns on its surface in the third embodiment of the present invention comprises a hand-held part 320 and a food contact part (not shown in FIG. 3). Preferably, the hand-held part 320 is made of plastics or silicon resin. The hand-held part 320 and food contact part can be manufactured by means of injection moulding, or stamping etc. Then a color layer is covered on the surface of the hand-held part by means of spraying, or silk screen etc., which means that a color layer is covered on the surface of the hand-held part 320, that is, there is a color layer covering the surface of the hand-held part 320. The color layer is divided into a first region 31 without a process of laser engraving and a second region 32 formed by laser engraving. The first region 31 is the region with oblique lines in the hand-held part 320 in FIG. 3, and the second region 32 is the blank region in the hand-held part 320 in FIG. 3.

The thickness of second region 32 is smaller than that of first region 31; preset patterns are formed by the first region 31 and second region 32. An engraving region and engraving depth are determined according to the preset patterns. That is, the position and size of second region 32 are determined; and the engraving depth is determined according to the thickness of second region 32. Preferably, the thickness of second region 32 is zero, which means the second region 32 has completely engraved by laser to reveal the surface of hand-held part 320. The color of color layer is different from that of the surface of hand-held part 320. The intrinsic color of color layer is black, while the intrinsic color of hand-held part is white. Therefore, the color of first region 31 is black while the color of second region 32 is the color of the intrinsic color of hand-held part 320 (i.e. white). Since the eventual colors of the first region 31 and the second region 32 are different from each other, patterns are formed on the surface of hand-held part 320.

A transparent protection layer is covered on the color layer by means of spraying, or silk screen etc. The protection layer can display the patterns, protect the color layer effectively and prevent the color layer from coming off. Meanwhile it can fill the concaves and convexes caused by engraving, so as to realize a flat surface of hand-held part 320. Stains do not easily remain on the flat surface of hand-held part 320; therefore the hand-held part 320 is easy to clean.

In the kitchenware with patterns on its surface according to the second embodiment of the present invention, the second region is divided into two regions comprising a first subregion and a second subregion, according to the differences of the thicknesses of color layer. It is needed to be understood that the second region also can be divided into more than two regions, the thickness of color layers are different from each other. The color of the color layer on regions with different thicknesses overlays on the color of the food contact part, as a result, different color effects may be formed.

In the kitchenware with patterns on its surface according to the above mentioned embodiments of the present invention, a color layer and patterns are set on the hand-held part and food contact part, respectively. It is needed to be understood that a color layer also can be set on the hand-held part and food contact part simultaneously and then patterns are formed.

In the kitchenware with patterns on its surface according to the above mentioned embodiments of the present invention, preferably, the protection layer is transparent. It is needed to be understood that the protection layer can also have its intrinsic color. The color of protection layer can overlay on the colors of the first region and second region to show different color effects. Thus patterns are formed on the surface of the kitchenware.

In the kitchenware with patterns on its surface according to the above mentioned embodiments of the present invention, preferably, patterns on the surface of kitchenware may be formed by dark grey coordinating with green and white coordinating with black. It is needed to be understood that other kinds of color can also be utilized for color coordinating, as long as the color of the color layer is different from that of hand-held part or that of food contact part.

A method for manufacturing the kitchenware with patterns on its surface is also disclosed in the present invention. The kitchenware with patterns on its surface in the second embodiment in FIG. 2 can be obtained through carrying out the following steps which comprising:

In the first step, a kitchenware with preset color is manufactured. The preset color here can be the real color of the kitchenware, which means the color of kitchenware is completely opaque. Alternately, the preset color of kitchenware here can also be transparent or semitransparent. The kitchenware comprises a hand-held part 220 and a food contact part 210, both of which can be manufactured by means of injection moulding, or compression moulding etc.

In the second step, a color layer is set on the surface of the food contact part 210 of the kitchenware by means of spraying, or silk screen etc.

In the third step, an engraving region and an engraving depth are determined according to the preset patterns. That is, the position and the size of the second region 22 are determined; and the engraving depth is determined according to the thickness of the second region 22. Preferably, the second region 22 here is specifically divided into a first subregion 23 and a second subregion 24. The engraved depth of first subregion 23 accounts for 0.1% to 30% of the thickness of the color layer. That is, 70% to 99.9% of the color layer of the first subregion 23 is remained, which can make the color layer of first subregion 23 overlay on and blend with the intrinsic color of the kitchenware much better. The color layer of the second subregion 24 is completely removed through laser engraving to reveal the intrinsic color of the food contact part 210. Then the color layer is engraved by laser to present patterns on the surface of the food contact part 210. Therefore the kitchenware in the second embodiment mentioned above can be manufactured.

In the fourth step, the color layer is covered with a protection layer by means of spraying, or silk screen etc.

In the second and third steps, a color layer is set on the surface of the food contact part of the kitchenware. Preferably, the engraved depth of first subregion accounts for 0.1% to 30% of the thickness of color layer, while the second subregion is completely removed through laser engraving. It is needed to be understood that the engraving depths of either the first subregion or the second subregion can be set as other values. Since the preset patterns set on the food contact part and/or hand-held part are dependent on the determined engraving region and engraving depth, different patterns can be achieved, same as the patterns in the first and third embodiments. The patterns can be manufactured on both food contact part and hand-held part simultaneously.

In the kitchenware with patterns on its surface and a method for manufacturing such kitchenware according to the above mentioned embodiments of the present invention, the kitchenware can be kitchen wares such as turners, spatulas or cooking spoon etc., as well as tableware such as spoon, or fork etc.

In the kitchenware with patterns on its surface and a method for manufacturing such kitchenware according to the above mentioned embodiments of the present invention, a color layer with preset patterns is set on the surface of a hand-held part and/or a food contact part. Moreover, the color layer may be divided into several regions with different thicknesses by means of laser engraving. The color of the color layer with different thicknesses overlays on the color of the hand-held part and/or the food contact part, thus resulting different color effects and forming patterns on the surface of the kitchenware. The patterns can be fine and aesthetic through laser engraving. A protection layer, which is capable of protecting the color layer effectively, preventing the color layer from coming off and realizing a flat surface of kitchenware, is set on the color layer. It is difficult for stains to remain on the flat surface of the kitchenware; therefore such kitchenware is easy to clean, improved non-stick performance and more healthy for usage. The manufacture method is simple and feasible.

The embodiments of the present invention are described with reference to accompanying drawings. However, the present invention is not limited by the above mentioned specific embodiments, which are exemplary but not limited. In the light of the invention, many forms, which are in the scope of the invention, can further be made therein by one of skill in the art without departing from the scope of the aim of the invention and claims.

What is claimed is:

1. A kitchenware with surface patterns, comprising:
a hand-held part and a food contact part, wherein the hand-held part and/or the food contact part are covered with a color layer;
the color layer is divided into a first region without a laser engraving process and a second region formed by a laser engraving process, a thickness of the second region being smaller than a thickness of the first region;
the first region and the second region forming a set of preset patterns; and
a protection layer covers the color layer.

2. The kitchenware with surface patterns of claim 1, wherein the second region is divided into at least one subregion according to differences of thicknesses of the color layer.

3. The kitchenware with surface patterns of claim 2, wherein the second region is divided into a first subregion (23) and a second subregion (24), a thickness of the first subregion (23) being smaller than the thickness of the first region, while the thickness of the first subregion (23) being larger than a thickness of the second subregion (24).

4. The kitchenware with surface patterns of claim 3, wherein the thickness of the first subregion (23) accounts for 70% to 99.9% of that of the first region, while the thickness of the second subregion (24) is zero.

5. The kitchenware with surface patterns of claim 1, wherein the thickness of the second region accounts for 70% to 99.9% of that of the first region.

6. The kitchenware with surface patterns of claim 1, wherein the thickness of the second region is zero.

7. The kitchenware with surface patterns of any of claim 1, wherein the kitchenware is tableware or a kitchen utensil.

8. The kitchenware with surface patterns of any of claim 2, wherein the kitchenware is tableware or a kitchen utensil.

9. The kitchenware with surface patterns of any of claim 3, wherein the kitchenware is tableware or a kitchen utensil.

10. The kitchenware with surface patterns of any of claim 4, wherein the kitchenware is tableware or a kitchen utensil.

11. The kitchenware with surface patterns of any of claim 5, wherein the kitchenware is tableware or a kitchen utensil.

12. The kitchenware with surface patterns of any of claim 6, wherein the kitchenware is tableware or a kitchen utensil.

13. A manufacture method of a kitchenware with surface patterns, comprising the following steps:
manufacturing a hand-held part and a food contact part with a preset color of the kitchenware;
covering a plurality of surfaces of the hand-held part and/or the food contact part of the kitchenware with a color layer;
determining an engraving region and an engraving depth according to formed preset patterns, and then engraving the color layer with a laser; and
covering the color layer with a protection layer.

14. The manufacture method of a kitchenware with surface patterns of claim 13, wherein in the manufacturing step, the hand-held part and the food contact part are manufactured by injection moulding or compression moulding; the hand-held part and the food contact part have an opaque color, or a semitransparent color, or a transparent color.

15. The manufacture method of a kitchenware with surface patterns of claim 14, wherein the kitchenware is tableware or a kitchen utensil.

16. The manufacture method of a kitchenware with surface patterns of claim 15, wherein the kitchenware is tableware or a kitchen utensil.
